(19) United States
(12) Patent Application Publication
(10) Pub. No.: US 2021/0148381 A1
(43) Pub. Date: May 20, 2021

(54) FAN MODULE

(71) Applicants: Inventec (Pudong) Technology Corporation, Shanghai (CN); INVENTEC CORPORATION, Taipei City (TW)

(72) Inventor: Yung-Chin HSU, Taipei City (TW)

(21) Appl. No.: 16/714,778

(22) Filed: Dec. 15, 2019

(30) Foreign Application Priority Data
Nov. 19, 2019 (CN) 201911136371.1

(51) Int. Cl. F04D 29/64; F04D 19/00; F04D 25/16; F04D 29/40

(52) U.S. Cl. CPC F04D 29/646; F04D 29/40; F04D 25/166; F04D 19/002

(57) ABSTRACT

A fan module includes a chassis and a plurality of fan structures. The chassis includes an outer casing and a plurality of isolation plates. The isolation plates are disposed inside the outer casing. The isolation plates isolate a plurality of first accommodation spaces inside the outer casing. Each of the isolation plates has a first outline and a first buckling portion. The fan structures are detachably accommodated inside the first accommodation spaces respectively. Each of the fan structures has a second outline and a second buckling portion. When one of the fan structures is accommodated inside the corresponding first accommodation space, the corresponding first buckling portion and the corresponding second buckling portion are buckled to each other in order to fix the relative position of the corresponding fan structure and the chassis. The first outline and the second outline match with each other.

### RELATED APPLICATIONS

This application claims priority to Chinese Application Serial Number 201911136371.1 filed Nov. 19, 2019, which is herein incorporated by reference.

### BACKGROUND

### Technical Field

The present disclosure relates to fan modules. More particularly, the present disclosure relates to fan modules installed in electric equipment.

### Description of Related Art

With the advancement of science and technology today, the demand of people for electronic equipment has been increasing. With regard to the design of electronic equipment, apart from the continuous enhancement of functions and operating efficiency, the durability is also an important point that the consumers concern about.

Therefore, in addition to pay full effort by the manufacturers to extend the working lives of each of the components inside the electronic equipment, how to replace those components inside the electronic equipment in a simple and quick manner is also undoubtedly an important direction of development for the industry.

### SUMMARY

A technical aspect of the present disclosure is to provide a fan module which can allow the user to install the fan structure into the chassis or take the fan structure away from the chassis in a simple and quick manner.

According to an embodiment of the present disclosure, a fan module includes a chassis and a plurality of fan structures. The chassis includes an outer casing and a plurality of isolation plates. The isolation plates are disposed inside the outer casing. The isolation plates isolate a plurality of first accommodation spaces inside the outer casing. Each of the isolation plates has a first outline and a first buckling portion. The fan structures are detachably accommodated inside the first accommodation spaces respectively. Each of the fan structures has a second outline and a second buckling portion. When one of the fan structures is accommodated inside the corresponding first accommodation space, the corresponding first buckling portion and the corresponding second buckling portion are buckled to each other in order to fix the relative position of the corresponding fan structure and the chassis. The first outline and the second outline match with each other.

In one or more embodiments of the present disclosure, each of the second buckling portions includes a hook. Each of the first buckling portions includes a through hole. When one of the fan structures is accommodated inside the corresponding first accommodation space, the corresponding hook at least partially penetrates through the corresponding through hole.

In one or more embodiments of the present disclosure, each of the hooks is configured to elastically deform relative to the corresponding isolation plate.

In one or more embodiments of the present disclosure, the isolation plates are arranged along a first direction. The fan structures are accommodated into the first accommodation spaces along a second direction. The first direction and the second direction are perpendicular to each other.

In one or more embodiments of the present disclosure, each of the fan structures includes a fan frame and a fan body. The fan frame includes a first side wall and a second side wall opposite to each other. The first side wall and the second side wall define a second accommodation space therebetween. The second buckling portion is located at the first side wall. The fan body is accommodated into the second accommodation space along a third direction. The third direction is perpendicular to the first direction and the second direction.

In one or more embodiments of the present disclosure, each of the fan frames further includes a connecting plate. The connecting plate is connected with the first side wall and the second sidewall. The connecting plate has a first recessed portion and a second recessed portion opposite to each other. The second side wall has a third recessed portion. The first recessed portion and the third recessed portion are mutually communicated.

In one or more embodiments of the present disclosure, each of the fan frames further includes at least one first positioning portion. Each of the fan bodies includes at least one second positioning portion. When one of the fan bodies is accommodated inside the corresponding second accommodation space, the corresponding first positioning portion and the corresponding second positioning portion are positioned with each other.

In one or more embodiments of the present disclosure, each of the first positioning portions is a protruding structure protruding from the corresponding fan frame along the third direction. Each of the second positioning portions is a through hole configured to allow the corresponding first positioning portion to penetrate through.

In one or more embodiments of the present disclosure, a face of each of the first side walls away from the corresponding second accommodation spaces defines the second outline. The second outline extends along the third direction. A face of the corresponding isolation plate facing to the corresponding first side wall defines the first outline. The first outline extends along the third direction.

In one or more embodiments of the present disclosure, a face of each of the second side walls away from the corresponding second accommodation space has a third outline. The third outline extends along the third direction. A face of the corresponding isolation plate facing to the corresponding second side wall has a fourth outline. The fourth outline extends along the third direction. The third outline and the fourth outline match with each other.

When compared with the prior art, the above-mentioned embodiments of the present disclosure have at least the following advantages:

(1) In the process that the user accommodates the fan structure inside the first accommodation space along the second direction, the second buckling portion is compressed by the isolation plate to deform elastically. Thus, the second buckling portion stores a certain amount of elastic potential energy. Until the hook reaches the position of the through hole, the second buckling portion releases the amount of elastic potential energy stored to recover and the hook at least partially penetrates through the through hole, such that the the relative position of the fan structure and the isolation plate is fixed. In this way, the procedure to install the fan structure to the chassis is also completed. Since the process to install the fan structure to the chassis is simple and quick without the usage of any extra component or tool, it is convenient to the user.

(2) When the user wants to take the fan structure away from the chassis, the user can put the index finger at the position of the first recessed portion and the third recessed portion, and then press on the connecting plate as a point of force exertion. The user can also press on the second buckling portion of the fan structure by the thumb, such that the second buckling portion deforms elastically towards the second recessed portion. After the hook leaves from the through hole because of the elastic deformation of the second buckling portion, the user can take the fan structure away from the chassis along the second direction. Since the process to take the fan structure away from the chassis is simple and quick without the usage of any extra component or tool, it is convenient to the user.

(3) When the fan body is accommodated inside the second accommodation space along the third direction, the first positioning portion of the fan frame and the second positioning portion of the fan body are positioned with each other, such that the relative position of the fan body and the fan frame is fixed. In this way, the process to install the fan body to the fan frame is simple and quick without the usage of any extra component or tool. Thus, it is convenient to the user.

### BRIEF DESCRIPTION OF THE DRAWINGS

The disclosure can be more fully understood by reading the following detailed description of the embodiments, with reference made to the accompanying drawings as follows:

FIG. 1 is a schematic view of a fan module according to an embodiment of the present disclosure;

FIG. 2 is an exploded view of the fan module of FIG. 1, in which the chassis and the fan structure are separated from each other;

FIG. 3 is a partially enlarged schematic view of the fan module of FIG. 1;

FIG. 4 is an exploded view of the fan structure of FIG. 1; and

FIG. 5 is a partially enlarged top view of the fan module of FIG. 1.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

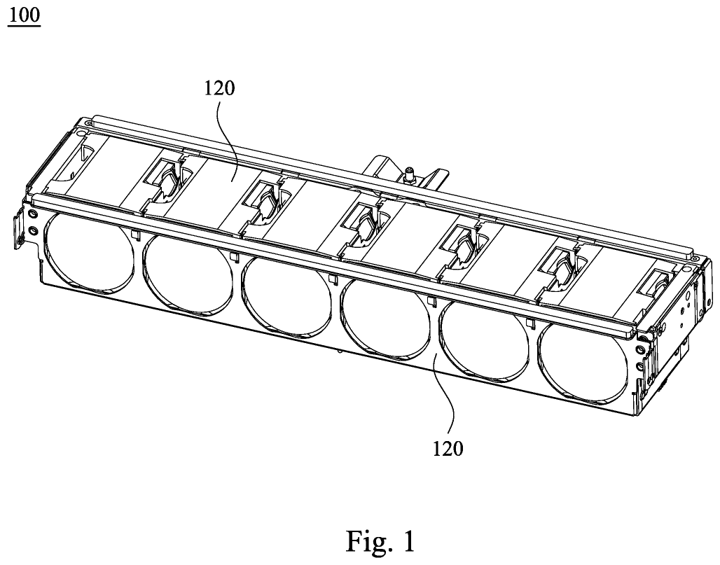

Reference is made to FIG. 1. FIG. 1 is a schematic view of a fan module 100 according to an embodiment of the present disclosure. In this embodiment, as shown in FIG. 1, a fan module 100 includes a chassis 110 and a plurality of fan structures 120. The fan module 100 is appropriate to be disposed inside an electric equipment (not shown) to carry out heat dissipation of the electric equipment.

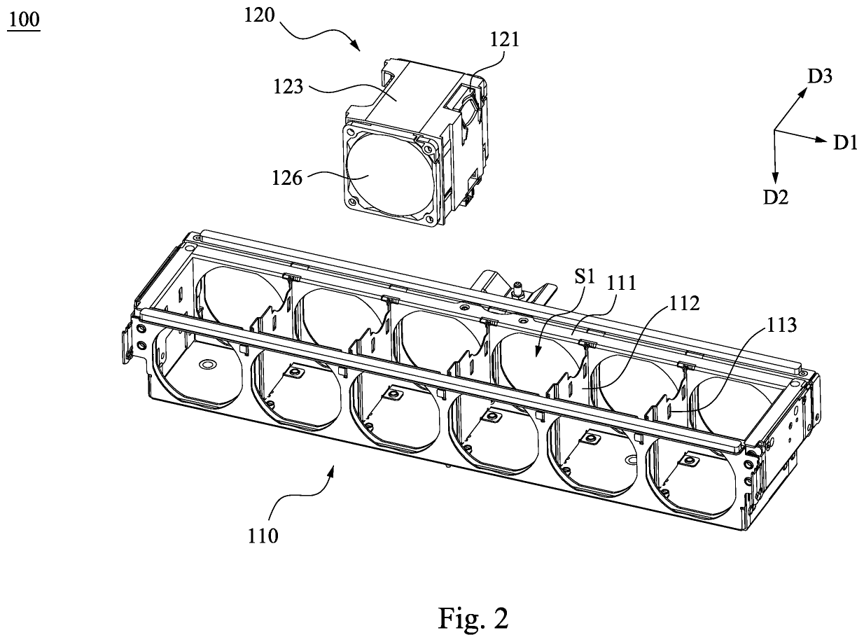

Reference is made to FIG. 2. FIG. 2 is an exploded view of the fan module 100 of FIG. 1, in which the chassis 110 and the fan structure 120 are separated from each other. For the sake of simplification of the figure, only one fan structure 120 is shown in FIG. 2. In this embodiment, as shown in FIG. 2, the chassis 110 includes an outer casing 111 and a plurality of isolation plates 112. The isolation plates 112 are disposed inside the outer casing 111. The isolation plates 112 isolate a plurality of first accommodation spaces S1 inside the outer casing 111. Each of the isolation plates 112 has a first buckling portion 113. The fan structures 120 are detachably accommodated inside the first accommodation spaces S1 respectively. Each of the fan structures 120 has a second buckling portion 121.

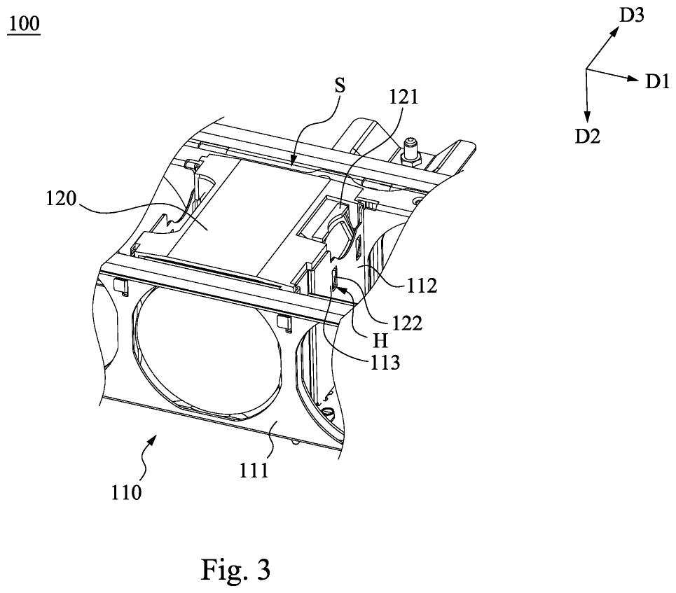

Reference is made to FIG. 3. FIG. 3 is a partially enlarged schematic view of the fan module 100 of FIG. 1. For the sake of simplification of the figure, only one fan structure 120 is shown in FIG. 3. In this embodiment, as shown in FIG. 2, when the fan structure 120 is accommodated inside the first accommodation space S1, the first buckling portion 113 of the isolation plate 112 and the second buckling portion 121 of the fan structure 120 are buckled to each other in order to fix the relative position of the fan structure 120 and the chassis 110.

In addition, as shown in FIG. 2, the isolation plates 112 of the chassis 110 are arranged along a first direction D1. Thus, the first accommodation spaces S1 are also arranged along the first direction D1. To be specific, the fan structures 120 can be accommodated into the first accommodation spaces S1 along a second direction D2. This means the fan structures 120 can be put into or taken away from the first accommodation spaces S1 along the second direction D2. The first direction D1 and the second direction D2 are perpendicular to each other.

In practical applications, as shown in FIG. 3, the second buckling portion 121 includes a hook 122. The first buckling portion 113 includes a through hole H. In the process that the user accommodates the fan structure 120 inside the first accommodation space S1 along the second direction D2, the second buckling portion 121 is compressed by the isolation plate 112 to deform elastically. Thus, the second buckling portion 121 stores a certain amount of elastic potential energy. Until the hook 122 reaches the position of the through hole H, the second buckling portion 121 releases the amount of elastic potential energy stored to recover and the hook 122 at least partially penetrates through the through hole H, such that the the relative position of the fan structure 120 and the isolation plate 112 is fixed. In this way, the procedure to install the fan structure 120 to the chassis 110 is also completed. Since the process to install the fan structure 120 to the chassis 110 is simple and quick without the usage of any extra component or tool, it is convenient to the user.

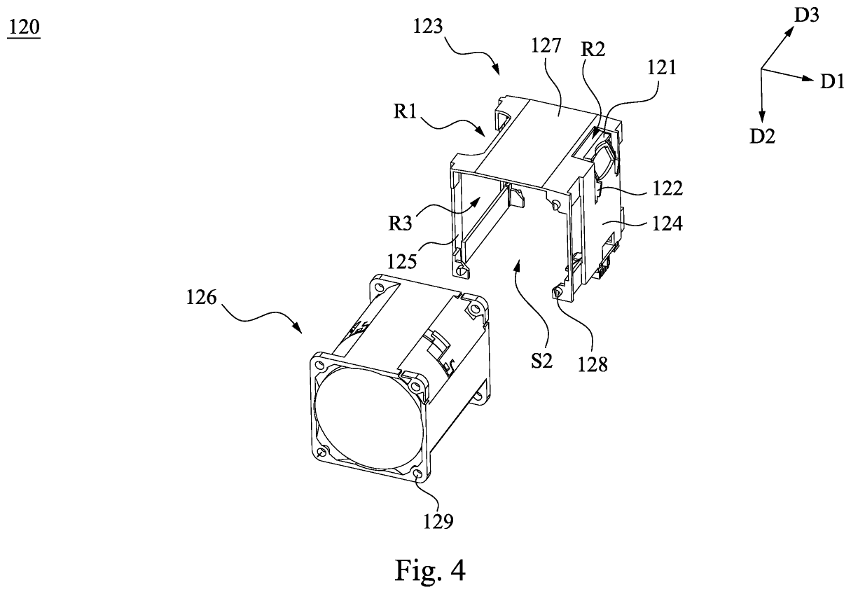

Reference is made to FIG. 4. FIG. 4 is an exploded view of the fan structure 120 of FIG. 1. Furthermore, in this embodiment, as shown in FIG. 4, the fan structure 120 includes a fan frame 123 and a fan body 126. The fan frame 123 includes a first side wall 124 and a second side wall 125 opposite to each other. The first side wall 124 and the second side wall 125 define a second accommodation space S2 therebetween. The second buckling portion 121 is located at the first side wall 124. The fan body 126 is accommodated into the second accommodation space S2 along a third direction D3. This means the fan body 126 enters into or leaves from the second accommodation spaces S2 along the third direction D3. The third direction D3 is perpendicular to the first direction D1 and the second direction D2.

In addition, as shown in FIG. 4, the fan frame 123 further includes a connecting plate 127. The connecting plate 127 is connected with the first side wall 124 and the second sidewall 125. The connecting plate 127, the first side wall 124 and the second sidewall 125 surround the second accommodation space S2. The connecting plate 127 has a first recessed portion R1 and a second recessed portion R2 opposite to each other. The second side wall 125 has a third recessed portion R3. The first recessed portion R1 of the connecting plate 127 and the third recessed portion R3 of the second sidewall 125 are mutually communicated.

In practical applications, when the user wants to take the fan structure 120 away from the chassis 110, as shown in FIGS. 3-4, the user can put, for example, the index finger at the position of the first recessed portion R1 and the third recessed portion R3, and then press on the connecting plate 127 as a point of force exertion. The user can also press on the second buckling portion 121 of the fan structure 120 by the thumb, such that the second buckling portion 121 deforms elastically towards the second recessed portion R2. After the hook 122 leaves from the through hole H because of the elastic deformation of the second buckling portion 121, the user can take the fan structure 120 away from the chassis 110 along the second direction D2. Since the process to take the fan structure 120 away from the chassis 110 is simple and quick without the usage of any extra component or tool, it is convenient to the user.

In this embodiment, as shown in FIG. 4, the fan frame 123 further includes at least one first positioning portion 128, and the fan body 126 includes at least one second positioning portion 129. When the fan body 126 is accommodated inside the second accommodation space S2 along the third direction D3, the first positioning portion 128 of the fan frame 123 and the second positioning portion 129 of the fan body 126 are positioned with each other, such that the relative position of the fan body 126 and the fan frame 123 is fixed. In this way, the process to install the fan body 126 to the fan frame 123 is simple and quick without the usage of any extra component or tool. Thus, it is convenient to the user.

In practical applications, the first positioning portion 128 is a protruding structure protruding from the fan frame 123 along the third direction D3. The second positioning portion 129 is a through hole. The through hole (the second positioning portion 129) of the fan body 126 is configured to allow the protruding structure (the first positioning portion 128) of the fan frame 123 to penetrate through. For example, as shown in FIG. 4, the quantity of the first positioning portion 128 is three. However, this does not intend to limit the present disclosure.

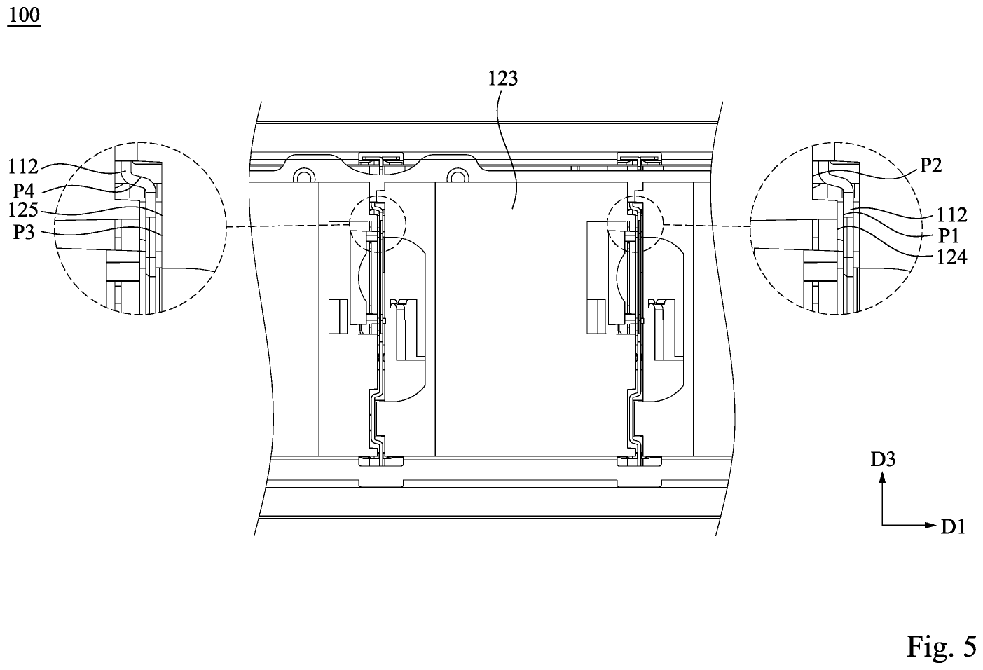

Reference is made to FIG. 5. FIG. 5 is a partially enlarged top view of the fan module 100 of FIG. 1. In this embodiment, as shown in FIG. 5, a face of the first side wall 124 of the fan frame 123 away from the second accommodation space S2 defines a second outline P2. The second outline P2 extends along the third direction D3. A face of the isolation plate 112 facing to the first side wall 124 defines a first outline P1. The first outline P1 also extends along the third direction D3. The first outline P1 and the second outline P2 match with each other. In this way, when the fan structure 120 is put into or taken away from the accommodation space S1 along the second direction D2, the first side wall 124 of the fan frame 123 and the isolation plate 112 avoid from each other and do not interfere with each other, providing an effect of guidance.

Similarly, as shown in FIG. 5, a face of the second side wall 125 of the fan frame 123 away from the second accommodation space S2 has a third outline P3. The third outline P3 extends along the third direction D3. A face of the isolation plate 112 facing to the second side wall 125 has a fourth outline P4. The fourth outline P4 extends along the third direction D3. The third outline P3 and the fourth outline P4 match with each other. In this way, when the fan structure 120 is put into or taken away from the accommodation space S1 along the second direction D2, the second side wall 125 of the fan frame 123 and the isolation plate 112 avoid from each other and do not interfere with each other, providing an effect of guidance.

In conclusion, when compared with the prior art, the aforementioned embodiments of the present disclosure have at least the following advantages:

(1) In the process that the user accommodates the fan structure inside the first accommodation space along the second direction, the second buckling portion is compressed by the isolation plate to deform elastically. Thus, the second buckling portion stores a certain amount of elastic potential energy. Until the hook reaches the position of the through hole, the second buckling portion releases the amount of elastic potential energy stored to recover and the hook at least partially penetrates through the through hole, such that the the relative position of the fan structure and the isolation plate is fixed. In this way, the procedure to install the fan structure to the chassis is also completed. Since the process to install the fan structure to the chassis is simple and quick without the usage of any extra component or tool, it is convenient to the user.

(2) When the user wants to take the fan structure away from the chassis, the user can put the index finger at the position of the first recessed portion and the third recessed portion, and then press on the connecting plate as a point of force exertion. The user can also press on the second buckling portion of the fan structure by the thumb, such that the second buckling portion deforms elastically towards the second recessed portion. After the hook leaves from the through hole because of the elastic deformation of the second buckling portion, the user can take the fan structure away from the chassis along the second direction. Since the process to take the fan structure away from the chassis is simple and quick without the usage of any extra component or tool, it is convenient to the user.

(3) When the fan body is accommodated inside the second accommodation space along the third direction, the first positioning portion of the fan frame and the second positioning portion of the fan body are positioned with each other, such that the relative position of the fan body and the fan frame is fixed. In this way, the process to install the fan body to the fan frame is simple and quick without the usage of any extra component or tool. Thus, it is convenient to the user.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A fan module, comprising:
a chassis comprising an outer casing and a plurality of isolation plates, the isolation plates being disposed inside the outer casing and isolating a plurality of first accommodation spaces inside the outer casing, each of the isolation plates having a first outline and a first buckling portion; and
a plurality of fan structures detachably accommodated inside the first accommodation spaces respectively, each of the fan structures having a second outline and a second buckling portion,
wherein when one of the fan structures is accommodated inside the corresponding first accommodation space, the corresponding first buckling portion and the corresponding second buckling portion are buckled to each other in order to fix a relative position of the corresponding fan structure and the chassis, and the first outline and the second outline match with each other.

2. The fan module of claim 1, wherein each of the second buckling portions comprises a hook, each of the first buckling portions comprises a through hole, when one of the fan structures is accommodated inside the corresponding first accommodation space, the corresponding hook at least partially penetrates through the corresponding through hole.

3. The fan module of claim 2, wherein each of the hooks is configured to elastically deform relative to the corresponding isolation plate.

4. The fan module of claim 1, wherein the isolation plates are arranged along a first direction, the fan structures are accommodated into the first accommodation spaces along a second direction, the first direction and the second direction are perpendicular to each other.

5. The fan module of claim 4, wherein each of the fan structures comprises:
a fan frame comprising a first side wall and a second side wall opposite to each other, the first side wall and the second side wall define a second accommodation space therebetween, the second buckling portion is located at the first side wall; and
a fan body accommodated into the second accommodation space along a third direction, the third direction is perpendicular to the first direction and the second direction.

6. The fan module of claim 5, wherein each of the fan frames further comprises:
a connecting plate connected with the first side wall and the second sidewall, the connecting plate has a first recessed portion and a second recessed portion opposite to each other, the second side wall has a third recessed portion, the first recessed portion and the third recessed portion are mutually communicated.

7. The fan module of claim 5, wherein each of the fan frames further comprises at least one first positioning portion, each of the fan bodies comprises at least one second positioning portion, when one of the fan bodies is accommodated inside the corresponding second accommodation space, the corresponding first positioning portion and the corresponding second positioning portion are positioned with each other.

8. The fan module of claim 7, wherein each of the first positioning portions is a protruding structure protruding from the corresponding fan frame along the third direction, each of the second positioning portions is a through hole configured to allow the corresponding first positioning portion to penetrate through.

9. The fan module of claim 5, wherein a face of each of the first side walls away from the corresponding second accommodation spaces defines the second outline, the second outline extends along the third direction, a face of the corresponding isolation plate facing to the corresponding first side wall defines the first outline, the first outline extends along the third direction.

10. The fan module of claim 5, wherein a face of each of the second side walls away from the corresponding second accommodation space has a third outline, the third outline extends along the third direction, a face of the corresponding isolation plate facing to the corresponding second side wall has a fourth outline, the fourth outline extends along the third direction, the third outline and the fourth outline match with each other.
